(19) United States
(12) Patent Application Publication
(10) Pub. No.: US 2009/0166066 A1
(43) Pub. Date: Jul. 2, 2009

(54) COPPER FOIL

(75) Inventors: Takemi MUROGA, Tsuchiura (JP); Kenji YOKOMIZO, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: HITACHI CABLE, LTD.

(21) Appl. No.: 12/342,165

(22) Filed: Dec. 23, 2008

(30) Foreign Application Priority Data
Dec. 27, 2007 (JP) 2007-337538

(51) Int. Cl. B32B 15/20; H05K 1/00

(52) U.S. Cl. 174/254; 428/220

(57) ABSTRACT

A copper foil according to the present invention has a B/A ratio within a range of 1.2 to 3.0, where B is an inclination value of a straight line in a straight portion of a rising area near the origin of a stress-strain curve of the copper foil which is measured before the copper foil is heated to 300° C.; and A is an inclination value of a straight line in a straight portion of a rising area near the origin of a stress-strain curve of the copper foil that is measured after the copper foil is heated to 300° C.

### CLAIM OF PRIORITY

The present application claims priority from Japanese patent application serial no. 2007-337538 filed on Dec. 27, 2007, the content of which is hereby incorporated by reference into this application.

### BACKGROUND OF THE INVENTION

1. Field of the Invention

The present invention relates to a copper foil having superior flexible fatigue property which is suitable for copper foils used as wiring materials in electric and electronic parts that need to have excellent flexibility and bending fatigue property.

2. Description of Related Art

Copper foils are widely used as wiring materials in electric and electronic parts that need to have excellent flexibility and bending fatigue property. A typical example of these parts is a flexible printed circuit (FPC) board. An FPC board is formed by routing wires made of foils as extremely thin as 40 μm or less on the front surface of an insulative board made of a material which is thin and has superior flexibility (e.g., a polyimide resin board). An FPC board is designed so that it has electric and mechanical characteristics suitable for mounting on various types of electronic devices. At present, an FPC board is widely used as a wring part, for example, in a bent part of a foldable (clamshell type) cellular phone, a movable part in an electronic machine device such as a digital camera or printer head, or a movable part in an electronic device such as a hard disk drive, digital versatile disc drive, and compact disk drive. A pure copper foil or copper alloy foil is usually used as a conductor layer for a wire in this type of FPC board. The pure copper foil and copper alloy foil will also be collectively called a copper foil in the description below.

Ordinary manufacturing process of an FPC board begins with the manufacturing of a prescribed copper foil. The copper foil is then joined to the surface of a base material (base film) made of, e.g., polyimide resin to form a copper clad laminate (CCL) board. The copper foil on the surface of the CCL board undergoes processing (patterning) by means of a process such as etching to form a so-called circuit wiring. Surface treatment is then carried out to protect the circuit wiring. This completes the manufacturing of the main elements of an FPC.

The above CCL process is carried out in one of two main methods. The copper foil is joined to a base material by using an adhesive, after which the adhesive is cured by being heated so that the copper foil and the base material are brought into tight contact with each other (three-layer CCL method, for example). Alternatively, the copper foil is directly joined to the surface of an insulative board without using an adhesive, after which the copper foil and insulative board are heated and pressurized so that they are brought into tight contact with each other for integration (two-layer CCL method).

Since an FPC board needs to have a high flexible fatigue property, an attempt to improve the flexible fatigue property of the copper foil itself has been made (see, e.g., JP-A-2001-58203).

In recent years along with development in downsizing, increase in the integration degree (higher density mounting) and higher performance of electronic equipment, the bending radius of an FPC board in its use is being decreased. Thus, there is a strong demand for FPC board to have a higher flexible fatigue property (durability against repetitive bending) than before. The flexible fatigue property of an FPC board is practically determined by the flexible fatigue property of the copper foil. It is therefore important to improve the flexible fatigue property of the copper foil itself.

### SUMMARY OF THE INVENTION

Under these circumstances, it is an objective of the present invention to provide a copper foil which has superior flexible fatigue property and that is suitable to flexible wiring materials such as for an FPC board.

According to one aspect of the present invention, a copper foil has a B/A ratio within a range of 1.2 to 3.0, where B is an inclination value of a straight line in a straight portion of a rising area near the origin of a stress-strain curve of the copper foil which is measured before the copper foil is heated to 300° C.; and A is an inclination value of a straight line in a straight portion of a rising area near the origin of a stress-strain curve of the copper foil which is measured after the copper foil is heated to 300° C.

In the above aspect of the present invention, the following modifications and changes can be made.

(i) Thickness of the copper foil is not less than 8 μm and not more than 40 μm.

(ii) A flexible printed circuit board comprises the above copper foil.

### ADVANTAGES OF THE INVENTION

According to the present invention, it is possible to provide a copper foil suitable for a flexible wiring material such as an FPC board and having superior flexible fatigue property.

### BRIEF DESCRIPTION OF THE DRAWINGS

FIG. 1 is a graph showing an example of a stress-strain curve of a copper foil, as well as an inclination value Δσ/Δε near the origin of the curve.

FIG. 2A is a graph which represents an example of a stress-strain curve before a copper foil in Example 1 is heat-treated; and FIG. 2B is a graph that represents a stress-strain curve after the copper foil is heat-treated.

FIG. 3A is a graph which represents an example of a stress-strain curve before a copper foil in Example 2 is heat-treated; and FIG. 3B is a graph that represents a stress-strain curve after the copper foil is heat-treated.

FIG. 4A is a graph which represents an example of a stress-strain curve before a copper foil in Example 3 is heat-treated; and FIG. 4B is a graph that represents a stress-strain curve after the copper foil is heat-treated.

FIG. 5A is a graph which represents an example of a stress-strain curve before a copper foil in Comparative example 1 is heat-treated; and FIG. 5B is a graph that represents a stress-strain curve after the copper foil is heat-treated.

### DETAILED DESCRIPTION OF THE PREFERRED EMBODIMENTS

A copper foil that embodies the present invention will be described below with reference to the accompanying drawings. However, the present invention is not limited to the embodiments described herein.

The copper foil in this embodiment, which is mainly used for wiring on a flexible printed circuit board, is made of pure copper or a copper alloy having a composition set for use on various printed circuit boards. It is preferable to use copper foils with a thickness of 8 to 40 μm. Copper foils of 8 to 18 μm thickness are further preferable for use. However, it will be appreciated that copper foils with a thickness of more than 40 μm or less than 8 μm can also be used.

The copper foil has a B/A ratio within a range of 1.2 to 3.0, where B is an inclination value of a straight portion near the origin of a stress-strain curve of the copper foil which is measured before the copper foil is heated to 300° C., and A is an inclination value of a straight portion near the origin of a stress-strain curve of the copper foil that is measured after the copper foil is heated to 300° C.

When the copper foil in this embodiment is laminated to a surface of a polyimide film board to form a flexible printed circuit board, the board can have an extremely superior flexible fatigue property; withstanding, e.g., more than 900,000 bending cycles. Accordingly, electronic components using the copper foil in this embodiment can have further improved flexible fatigue property.

The inventors studied in detail changes in the flexibility (changes in mechanical properties) of copper foils which were caused by heat treatment, and found that when changes (ratio of) in inclination values of straight lines in straight portions of rising areas near the origins of stress-strain curves between before and after the heat treatment, the inclination values being defined in this description, are within a prescribed range, the copper foil exhibits superior flexible fatigue property. These inclination values of straight lines do not necessarily match the concept of elasticity, which is academically defined, as described below, and are independent of absolute values. Only when a ratio (B/A) of inclinations values between before and after the heat treatment is in the prescribed range, an effect is obtained.

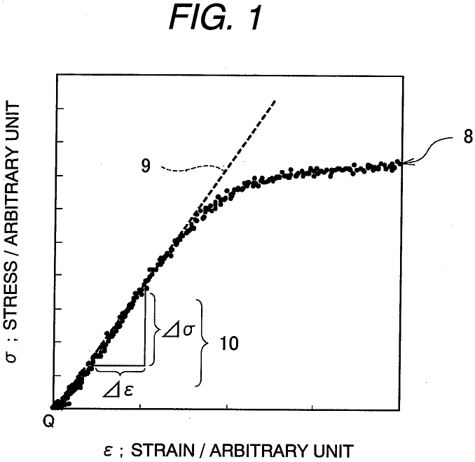

FIG. 1 is a graph showing an example of a stress-strain curve of a copper foil, as well as an inclination value Δσ/Δε near the origin of the curve. The inclination value Δσ/Δε 10 of the straight line 9 in the first rising area of the stress-strain curve as exemplified in FIG. 1 is usually called an elastic coefficient in the field of strength of the material. Basically, the value of the elastic coefficient is a value of a physical property; it does not essentially change even when the copper foil is heated, only the range of the elastic area changes. For reference, the elastic coefficient of copper is about 120 GPa. And, the copper foil is a polycrystalline body.

The copper foil in the present invention is as thin as 8 to 40 μm. In particular, the elastic range substantially changes depending on the degree of the flexibility. As the flexibility increases, the elastic range is narrowed, making it hard to carry out measurements of the elastic coefficient.

Since “B” (for the copper foil before heat treatment) and “A” (for the copper foil after heat treatment) described above, which are defined in the present invention, are not true values of the elastic coefficient, “A” and “B” are called as “inclination values of straight lines in linear portions of rising areas near the origins of the stress-strain curves”. Therefore, “B” (for the copper foil before heat treatment) and “A” (for the copper foil after heat treatment) are just inclination values of linear portions, which are obtained by a particular measurement method, and do not necessarily conform to the academic concept of the elastic coefficient.

The inclination values A and B in linear portions of rising areas near the origins of the stress-strain curves, which are stipulated in the embodiment of the present invention, will be now specifically described.

In the example of FIG. 1, a graph with stress a on the vertical axis and strain E on the horizontal axis is used to represent the stress-strain curve 8. The inclination value 10 represented by Δσ/Δε near the origin in the substantially linear portion along the straight line 9 on the stress-strain curve 8, which extends from the origin, is in this embodiment stipulated as the inclination value A or B in the straight portion of the rising area near the origin of the stress-strain curve.

To obtain this stress-strain curve 8, it is possible to adopt a measurement method in which an ordinary tensile test apparatus is used and a displacement gage is attached to the copper foil. A tensile load applied to the copper foil is gradually changed, and displacement (strain) of the copper foil, which changes according to the change in tensile load, is measured and plotted on a graph. Other various methods can also be used if precise measurements of changes in strain in response to changes in stress are possible near the origin.

As described above, the preferable range of the B/A ratio, which is a ratio of inclination values between before and after heat treatment, is not less than 1.2 and not more than 3.0. If the B/A ratio is less than the lower limit, 1.2, a sufficient effect in improving the flexible fatigue property by heating is less likely to be obtained. Conversely, if the B/A ratio is greater than the upper limit, 3.0, improvement of the flexible fatigue property is adversely affected by unknown factors. Accordingly, this upper limit should be set.

The use of the copper foil in this embodiment is not limited to a flexible circuit board; the copper foil can also be used on other types of printed circuit boards and general circuit boards which need superior flexibility and flexible fatigue property. In addition to these circuit boards, the copper foil can be also applied to wiring parts of various electric and electronic components, springs for switches, and connectors which need superior conductivity and flexible fatigue property.

The quality of the copper foil can be known in a short period of time according to the B/A ratio between before and after heat treatment in this embodiment; evaluation of a flexible fatigue property measurement does not need to be carried out by taking a long time, e.g., for one to five days. From the viewpoint of quality control, as well, the effect of the present invention is large.

### EXAMPLES

Examples of copper foils for wiring components, as described in the above embodiment, will be described.

Several types of 18 μm thick copper foils were prepared, which were formed under different rolling conditions and different process annealing conditions. Some of these copper foils were cut into a length of 200 mm and a width of 15 mm to obtain rectangular test pieces for tensile testing. Other copper foils were cut into a length of 220 mm and a width of 12.5 mm to obtain rectangular test pieces for flexible fatigue property testing.

Measurement of the inclination values A and B substantially conformed to ‘Method of tensile testing for metallic materials’ in JIS Z 2241, in which an universal testing machine AG-I from SHIMADZU CORPORATION and a strain gage SG50-10 also from SHIMADZU CORPORATION (serial number 620051-04, 5-mm score distance) were used.

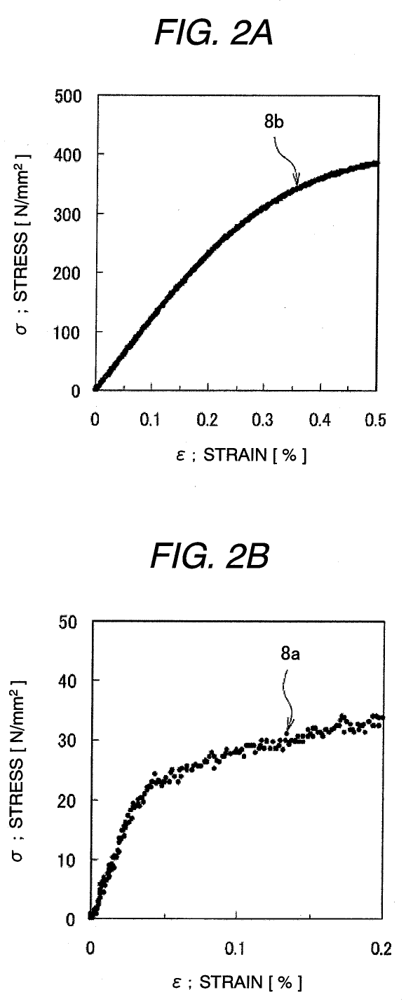

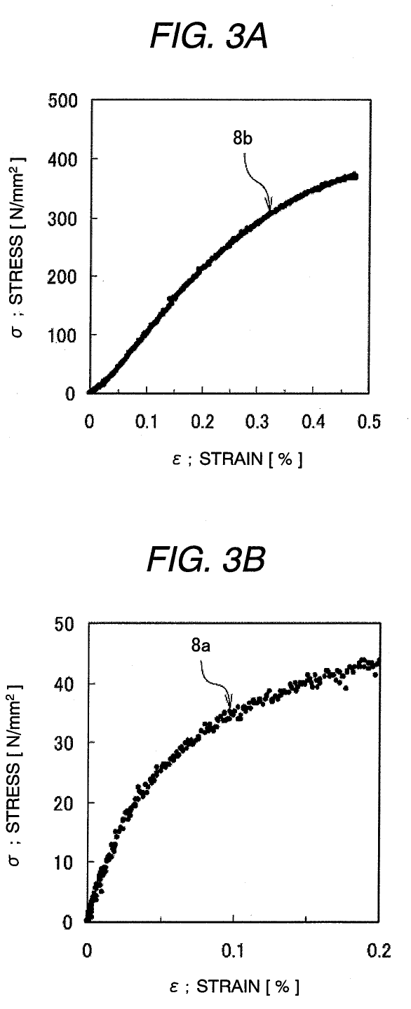

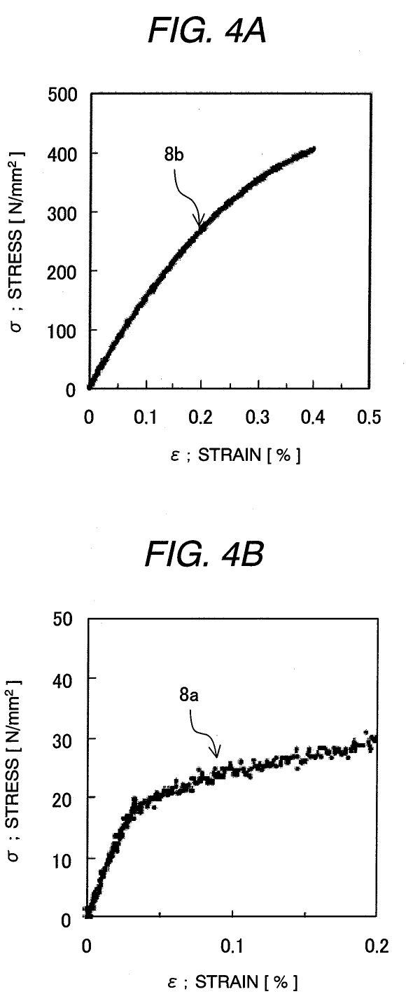

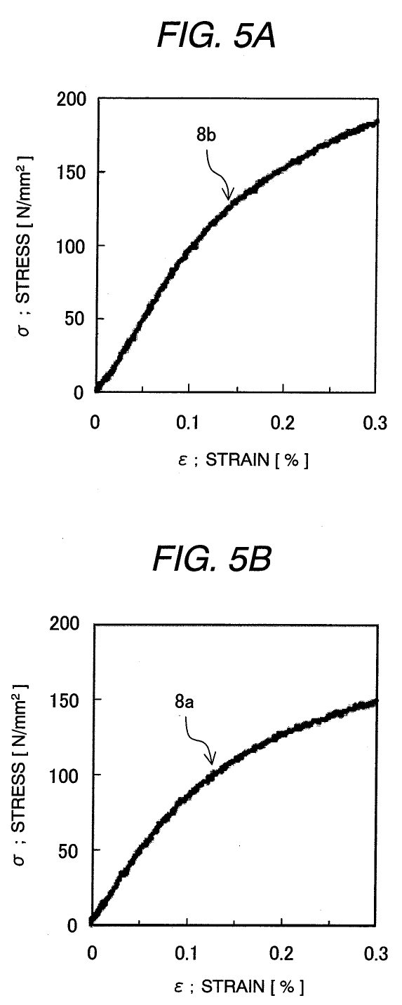

FIG. 2A is a graph which represents an example of a stress-strain curve 8b before a copper foil in Example 1 is heat-treated; and FIG. 2B is a graph that represents a stress-distortion curve 8a after the copper foil is heat-treated. FIG. 3A is a graph which represents an example of a stress-strain curve 8b before a copper foil in Example 2 is heat-treated; and FIG. 3B is a graph that represents a stress-strain curve 8a after the copper foil is heat-treated. FIG. 4A is a graph which represents an example of a stress-strain curve 8b before a copper foil in Example 3 is heat-treated; and FIG. 4B is a graph that represent a stress-strain curve 8a after the copper foil is heat-treated. FIG. 5A is a graph which represents an example of a stress-strain curve 8b before a copper foil in Comparative example 1 is heat-treated; and FIG. 5B is a graph that represents a stress-strain curve 8a after the copper foil is heat-treated.

The inclination B (=Δσ/Δε) near the origin of the stress-strain curve 8b was measured for each of these copper foil test pieces before they were heat-treated. And also, the inclination A (=Δσ/Δε) near the origin of the stress-strain curve 8a was measured for each of these copper foil test pieces after they were heat-treated at 300° C. for five minutes. Table 1 indicates the values of B, A, and B/A for the copper foils in Examples 1 to 3 and Comparative example 1. The values of B and A are averages of five specimens.

TABLE 1

| | | A (Δσ/Δε) | |
|---|---|---|---|
| | | after heat | |
| | B (Δσ/Δε) | treatment | |
| | before heat | (at 300° C. for | |
| | treatment | 5 minutes) | |
| | [GPa] | [GPa] | B/A |
| Example 1 | 125.3 | 76.9 | 1.63 |
| Example 2 | 120.1 | 85.9 | 1.40 |
| Example 3 | 151.6 | 58.7 | 2.60 |
| Comparative | 105.0 | 93.5 | 1.12 |
| example 1 | | | |

The “B before heat treatment” column in Table 1 indicates the inclination value B for each copper foil specimen. The “A after heat treatment” column in Table 1 indicates the value of inclination A for each copper foil specimen. The unit of these values is GPa.

The B/A column in Table 1 indicates the calculations of the B/A ratio in Examples 1 to 3 and Comparative example 1. The value for the copper foil in Example 1 was 1.63, the value for the copper foil in Example 2 was 1.40, and the value for the copper foil in Example 3 was 2.60. These values of the B/A ratio fell within the range of 1.2 to 3.0, which was stipulated as the preferable range in the above embodiments. By comparison, the value for Comparative example 1 was 1.12, which was smaller than the lower limit, 1.2, of the preferable range.

To directly confirm the flexible fatigue property of the copper foils in Examples 1 to 3 and Comparative example 1 through measurements, repetitive bending tests were carried out in compliance with the IPC (Institute for Interconnecting and Packing Electronics Circuits) standard. In this test, a high-speed FPC sliding bending test apparatus SEK-31B2S from Shin-Etsu Engineering Co., Ltd. was used. The bending radius was 2.5 mm, the amplitude stroke was 10 mm, and the bending frequency was 25 Hz (amplitude velocity of 1500 cycles/min). The number of cycles to failure the copper foil was determined as a flexible fatigue life. Table 2 indicates the flexible fatigue life (number of cycles to failure) of the copper foils in Examples 1 to 3 and Comparative example 1. The value of each example was an average of five specimens.

TABLE 2

| | Number of cycles to failure |
|---|---|
| | (Cycles until rupture of bent portion) |
| Example 1 | 3,306,000 |
| Example 2 | 992,600 |
| Example 3 | 2,011,000 |
| Comparative | 210,300 |
| example 1 | |

As shown in Table 2, the flexible fatigue lives of the copper foils in Examples 1 to 3 were respectively 3,306,000 cycles, 992,600 cycles, and 2,011,000 cycles. It was confirmed that these copper foils had enough flexible fatigue property to withstand more than 900 thousand cycles (or more than about one million cycles). By comparison, the flexible fatigue life of the copper foil in Comparative example 1 was 210,300, which was just about one-fifth the flexible fatigue life in Example 2 that was 992,600 cycles and the lowest in Examples.

In addition to the copper foils described above, repetitive bending tests were carried for test pieces of 12 and 35 μm thickness as Examples 4 and 5 in the same manner as described above (their stress-strain curves are not shown). The values themselves (absolute values) of B, A, and the flexible fatigue life were different from the values in Tables 1 and 2. However, it was confirmed that when copper foils in Examples had a B/A ratio within the preferable range of 1.2 to 3.0, they each achieved a flexible fatigue life which was five times or more as long as that of the copper foil in Comparative example 1.

From the experiments in the examples, it was also confirmed that the flexible fatigue property of a copper foil, which was confirmed by its flexible fatigue life, could be accurately evaluated based on the ratio (B/A) of the inclination value B on a stress-strain curve of the copper foil before heat treatment to the inclination value A on a stress-strain curve after heat treatment.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A copper foil, wherein: the copper foil has a B/A ratio within a range of 1.2 to 3.0, where B is an inclination value of a straight line in a straight portion of a rising area near the origin of a stress-strain curve of the copper foil which is measured before the copper foil is heated to 300° C.; and A is an inclination value of a straight line in a straight portion of a rising area near the origin of a stress-strain curve of the copper foil which is measured after the copper foil is heated to 300° C.

2. The copper foil according to claim 1, wherein:
the thickness of the copper foil is not less than 8 μm and not more than 40 μm.

3. A flexible printed circuit board, comprising the copper foil according to claim 1.
